(19) United States
(12) Patent Application Publication
(10) Pub. No.: US 2005/0074554 A1
(43) Pub. Date: Apr. 7, 2005

(54) Method of forming inter-metal dielectric layer structure

(76) Inventors: Shiu-Ko Jangjian, Fengshan City (TW); Sheng-Wen Chen, Shinjuang City (TW); Miao-Cheng Liao, Tstung Shiang (TW); Hung-Jui Chang, Shetou Shiang (TW); Ming-Hui Lin, Jiali Jen (TW); Ying-Lang Wang, Lungjing Shiang (TW)

Correspondence Address: SNELL & WILMER;ONE ARIZONA CENTER, 400 EAST VAN BUREN, PHOENIX, AZ, 850040001, US

(21) Appl. No.: 10/679,764

(22) Filed: Oct. 6, 2003

(51) Int. Cl. C23C 16/26; B32B 17/06

(52) U.S. Cl. 427/249.1; 427/255.6; 427/255.7; 428/698; 428/426; 428/432

(57) ABSTRACT

A inter-metal dielectric layer structure and the method of the same are provided. The method includes the following steps. A process gas is introduced to form a low-k dielectric layer over the substrate. A reactant gas is in situ introduced to etch the low-k dielectric layer back and to react with the process gas to form a dielectric layer containing an extra element on the low-k dielectric layer. The extra element is provided by the reactant gas. A volume ratio of the reactant gas to the process gas is larger than about 2. The reactant gas may be a nitrogen fluoride (NF₃) gas for providing extra nitrogen (N) or a carbon fluoride (CₓF_{y}) gas for providing extra carbon (C).

### FIELD OF INVENTION

The present invention relates to a method of forming an inter-metal dielectric layer structure.

### BACKGROUND OF THE INVENTION

As semiconductor device density increases, integrated circuits generally include more levels of metallization. One common method of forming electrical interconnection between vertically spaced metallization levels is damascene process. Dual damascene process forms the via and trench in the dielectric layer simultaneously and therefore reduces the process steps.

A typical low-k inter-metal dielectric (IMD) layer structure 100 for dual damascene process is shown in FIG. 1. This structure 100 includes a substrate 102, a first barrier/etch stop layer 104, a first low-k dielectric layer 106, a middle etch stop layer 108, a second low-k dielectric layer 110 and a second barrier/etch stop layer 112. Herein the term “low-k” means having a dielectric constant less than that of SiO₂, which is 3.9. The layers 104, 108 and 112 are of silicon nitride/carbide. However, the typical IMD layer structure 100 shown in FIG. 1 has the following drawbacks.

1. The low-k dielectric layers 106, 110 and the silicon nitride/carbide layers have to be formed in different process chambers. Therefore, 5 process steps are needed to fabricate this structure 100, and then the throughput is limited.

2. The effective dielectric constant of this structure 100 is still high, since the dielectric constant of silicon nitride is about 7 and that of silicon carbide is about 5.

3. Dangling Si bonds exist at the interface between the low-k dielectric layer and the silicon nitride/carbide layer and lead to an inferior interface. An inferior interface in turn results in inferior mechanical strength of this structure 100.

### SUMMARY OF THE INVENTION

One aspect of the present invention provides a method of forming an inter-metal dielectric layer structure with increased throughput. The structure thus formed has a lower effective dielectric constant and better mechanical strength.

Another aspect of the present invention provides a middle etch stop layer formed by in situ introducing a reactant gas during formation of the low-k dielectric layer. Namely, the first low-k dielectric layer, the middle etch stop layer and the second low-k dielectric layer are formed in a single process chamber during one pump down. Therefore, only 3 steps are needed to form a structure, thus the throughput is elevated.

Moreover, the middle etch stop layer formed by the invention would be a low-k dielectric layer containing an extra element provided by the in situ introduced reactant gas. Therefore, the middle etch stop layer of the present invention has a lower dielectric constant than that of silicon nitride/carbide, so that the effective dielectric constant could be reduced. The extra element could modify the interface between the middle etch stop layer and the low-k dielectric layer to make it stronger. One more benefit is that the in situ introduced reactant gas could clean the process chamber at the same time, thus less time is needed for post-cleaning and the throughput is further increased.

The method according to the present invention includes the following steps. A process gas is introduced to form a low-k dielectric layer over the substrate. A reactant gas is in situ introduced to etch back the low-k dielectric layer and to react with the process gas to form a dielectric layer containing an extra element on the low-k dielectric layer. The extra element is provided by the reactant gas. A volume ratio of the reactant gas to the process gas is larger than about 2. The reactant gas may be a nitrogen fluoride (NF₃) gas for providing extra nitrogen (N) or a carbon fluoride (CₓF_{y}) gas for providing extra carbon (C).

### BRIEF DESCRIPTION OF THE DRAWINGS

For a more complete understanding of the present invention, reference is now made to the following descriptions taken in conjunction with the accompanying drawings. Similar notation number represents similar element.

FIG. 1 is a cross-sectional diagram of a low-k inter-metal dielectric (IMD) layer structure according to the prior art;

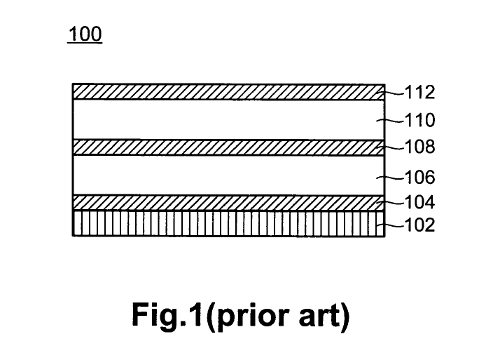

FIGS. 2(a)-(c) are cross-sectional diagrams illustrating a first exemplary embodiment of the present invention;

FIG. 3 is a cross-sectional diagram illustrating the formation of a first low-k dielectric layer and a middle etch stop layer in the first exemplary embodiment;

FIGS. 4(a)-(c) are cross-sectional diagrams illustrating a second exemplary embodiment of the present invention; and

FIG. 5 is a cross-sectional diagram illustrating the formation of a first low-k dielectric layer and a middle etch stop layer in the second exemplary embodiment.

### DETAILED DESCRIPTION

In the following embodiments, the low-k dielectric layers are of black diamond, which is one of organosilicate glass (OSG) and formed by the process gas 3MS+O₂. However, the low-k dielectric layers may be of any organic low-k dielectric material, such as organofluorosilicate glass (OFSG), or the like.

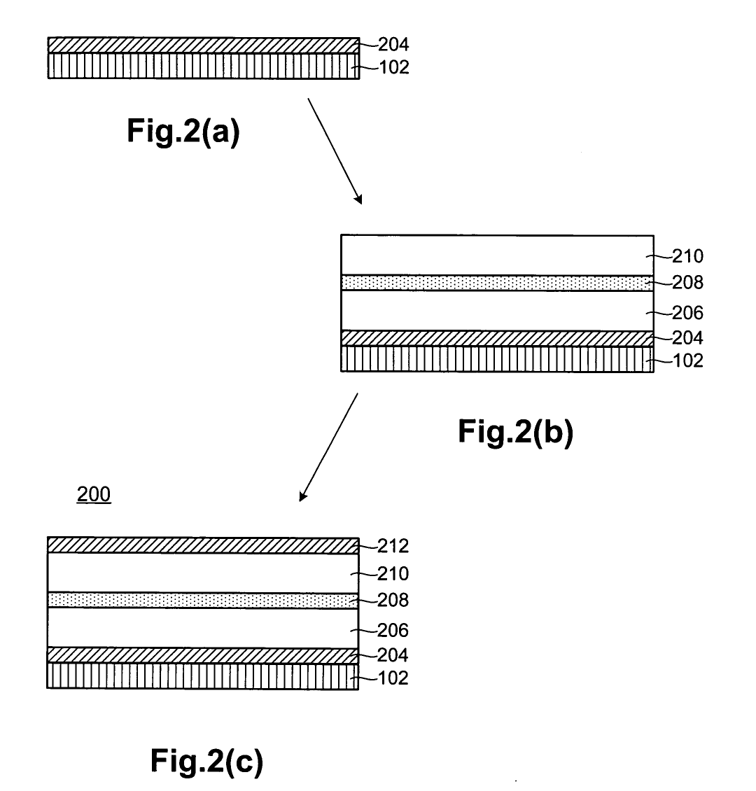

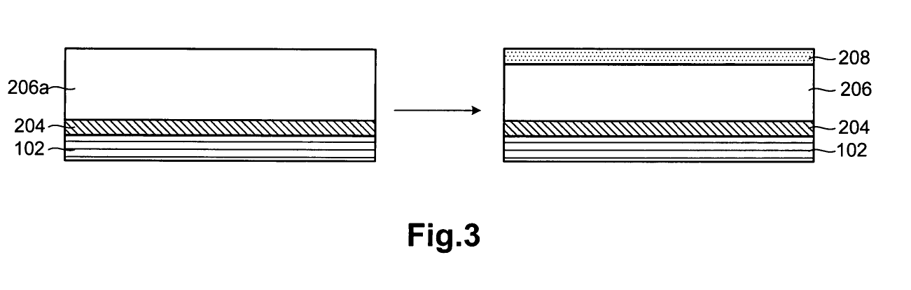

The first exemplary embodiment includes the following steps. A first nitride layer 204 is formed on a substrate 102, as shown in FIG. 2(a). Then a first black diamond layer 206, a middle etch stop layer 208 and a second black diamond layer 210 are sequentially formed on the first nitride layer 204, as illustrated in FIG. 2(b). And a second nitride layer 212 is formed on the second black diamond layer 210, as shown in FIG. 2(c). The formation of the first black diamond layer 206 and the middle etch stop layer 208 is illustrated in FIG. 3. A black diamond layer 206a is formed in advance by introducing a process gas including 3MS and O₂. Then a reactant gas, nitrogen fluoride (NF₃), is in situ introduced to etch back the black diamond layer 206a and to react with the process gas to form a dielectric layer 208 containing nitrogen. Thus the first black diamond layer 206 and the middle etch stop layer 208 are formed. The volume ratio of the NF₃ gas to the process gas is larger than about 2. The thickness of the first black diamond layer 206 is about 200˜1000 nm. And the thickness of the middle etch stop layer 208 is smaller than about 100 nm.

The structure formed according to the first embodiment is suitable for devices having feature below 0.13 um. Instead of being formed in different process chambers, the layers 206, 208 and 210 of this exemplary embodiment are formed in a single process chamber during one pump down. Therefore, rather than 5 steps, only 3 steps are needed to form an IMD layer structure according to this embodiment, so that the throughput can be increased. The middle etch stop layer 208 is essentially a black diamond layer with extra nitrogen. Therefore, the effective dielectric constant of the structure according to this embodiment is not as high as that of the typical structure. Besides, the nitrogen contained in the layer 208 could nitrogenize the dangling Si bond at the interface of the layer 206, and the interface quality is better. Moreover, the NF₃ gas facilitates process chamber cleaning, so that the throughput is further improved.

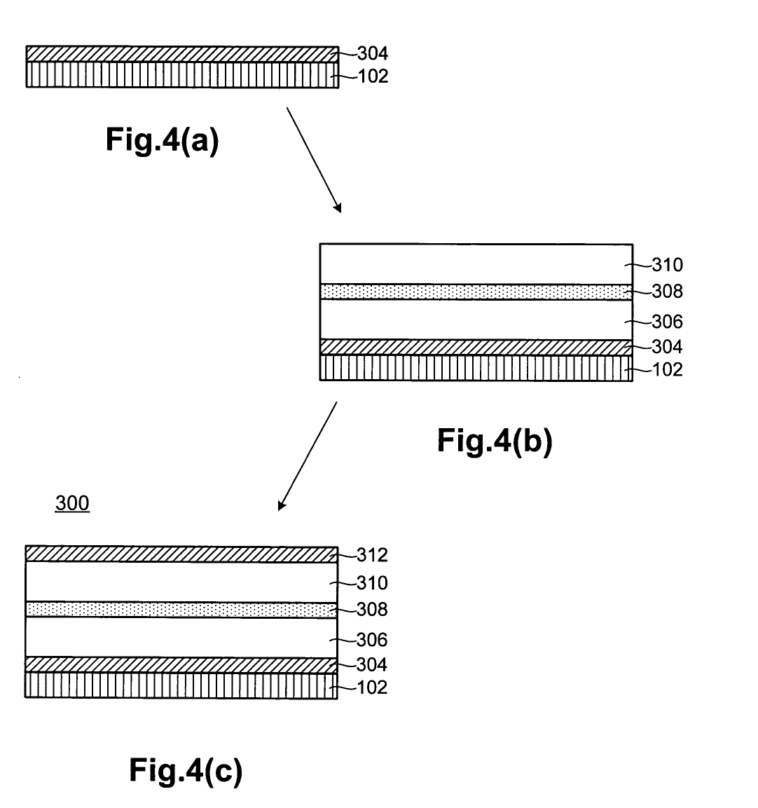

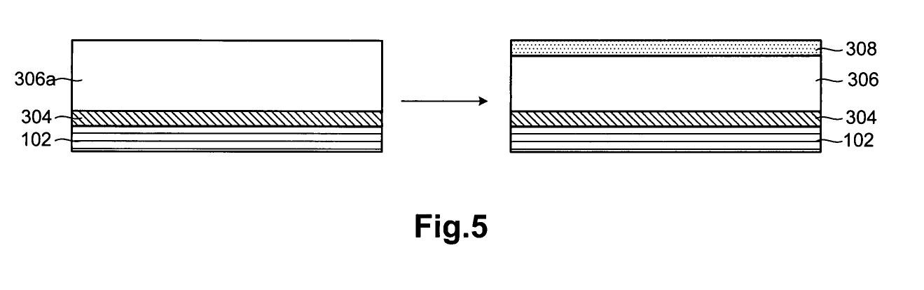

The second exemplary embodiment includes the following steps. A first carbide layer 304 is formed on a substrate 102, as shown in FIG. 4(a). Then a first black diamond layer 306, a middle etch stop layer 308 and a second black diamond layer 310 are sequentially formed on the first carbide layer 304, as illustrated in FIG. 4(b). And a second carbide layer 312 is formed on the second black diamond layer 310, as shown in FIG. 4(c). The formation of the first black diamond layer 306 and the middle etch stop layer 308 is illustrated in FIG. 5. A black diamond layer 306a is formed in advance by introducing a process gas including 3MS and O₂. Then a reactant gas, carbon fluoride (CₓF_{y}), is in situ introduced to etch back the black diamond layer 306a and to react with the process gas to form a dielectric layer 308 containing carbon. Thus the first black diamond layer 306 and the middle etch stop layer 308 are formed. The volume ratio of the CₓF_{y} gas to the process gas is larger than about 2. The thickness of the first black diamond layer 306 is about 200˜1000 nm. And the thickness of the middle etch stop layer 308 is smaller than about 100 nm.

The structure formed according to the second embodiment is suitable for devices having feature below 0.13 um, or even 90 nm. Instead of being formed in different process chambers, the layers 306, 308 and 310 of this exemplary embodiment are formed in a single process chamber during one pump down. Therefore, rather than 5 steps, only 3 steps are needed to form an IMD layer structure according to this embodiment, so that the throughput can be increased. The middle etch stop layer 308 is essentially a black diamond layer with extra carbon. Therefore, the effective dielectric constant of the structure according to this embodiment is not as high as that of the typical structure. Besides, the carbon contained in the layer 308 could carbonize the dangling Si bond at the interface of the layer 306, and then the interface quality is better. Moreover, the CₓF_{y} gas facilitates process chamber cleaning, so that the throughput is further improved.

While this invention has been described with reference to the illustrative embodiments, these descriptions should not be construed in a limiting sense. Various modifications of the illustrative embodiment, as well as other embodiments of the invention, will be apparent upon reference to these descriptions. It is therefore contemplated that the appended claims will cover any such modifications or embodiments as falling within the true scope of the invention and its legal equivalents.

1. A method of forming an inter-metal dielectric layer structure over a substrate, said method comprising:
introducing a process gas to form a low-k dielectric layer over said substrate; and
in situ introducing a reactant gas to etch back said low-k dielectric layer and to react with said process gas to form a dielectric layer containing an extra element on said low-k dielectric layer;
wherein said extra element is provided by said reactant gas.

2. The method of claim 1, wherein a volume ratio of said reactant gas to said process gas is larger than about 2.

3. The method of claim 1, wherein said reactant gas includes a nitrogen fluoride (NF₃) gas and said extra element includes nitrogen.

4. The method of claim 3, further comprising:
forming a first nitride layer between said low-k dielectric layer and said substrate; and
forming a second nitride layer over said dielectric layer.

5. The method of claim 1, wherein said reactant gas includes a carbon fluoride (CₓF_{y}) gas and said extra element includes carbon.

6. The method of claim 5, further comprising:
forming a first carbide layer between said low-k dielectric layer and said substrate; and
forming a second carbide layer over said dielectric layer.

7. The method of claim 1, wherein said low-k dielectric layer is an organic low-k dielectric layer.

8. The method of claim 7, wherein said organic low-k dielectric layer is an organosilicate glass (OSG) layer.

9. The method of claim 8, wherein said organosilicate glass layer is a black diamond layer.

10. The method of claim 7, wherein said organic low-k dielectric layer is an organofluorosilicate glass (OFSG) layer.

11. A method of forming an inter-metal dielectric layer structure over a substrate, said method comprising:
introducing a process gas to form a low-k dielectric layer over said substrate; and
in situ introducing a reactant gas to etch back said low-k dielectric layer and to react with said process gas to form a dielectric layer containing an extra element on said low-k dielectric layer;
wherein said extra element is provided by said reactant gas, a volume ratio of said reactant gas to said process gas is larger than about 2.

12. The method of claim 11, wherein said reactant gas includes a nitrogen fluoride (NF₃) gas and said extra element includes nitrogen, said method further comprising:
forming a first nitride layer between said low-k dielectric layer and said substrate; and
forming a second nitride layer over said dielectric layer.

13. The method of claim 11, wherein said reactant gas includes a carbon fluoride (CₓF_{y}) gas and said extra element includes carbon, said method further comprising:
forming a first carbide layer between said low-k dielectric layer and said substrate; and
forming a second carbide layer over said dielectric layer.

14. The method of claim 11, wherein said low-k dielectric layer is a black diamond layer.

15. The method of claim 11, wherein said low-k dielectric layer is an organofluorosilicate glass (OFSG) layer.

16. An inter-metal dielectric layer structure formed over a substrate, said inter-metal dielectric layer structure comprising:
a low-k dielectric layer formed over said substrate; and
a dielectric layer containing an extra element formed on said low-k dielectric layer.

17. The inter-metal dielectric layer structure of claim 16, wherein said extra element includes nitrogen.

18. The inter-metal dielectric layer structure of claim 17, further comprising:
a first nitride layer formed between said low-k dielectric layer and said substrate; and
a second nitride layer formed over said dielectric layer.

19. The inter-metal dielectric layer structure of claim 16, wherein said extra element includes carbon.

20. The inter-metal dielectric layer structure of claim 19, further comprising:
a first carbide layer formed between said low-k dielectric layer and said substrate; and
a second carbide layer formed over said dielectric layer.

21. The inter-metal dielectric layer structure of claim 16, wherein said low-k dielectric layer is an organic low-k dielectric layer.

22. The inter-metal dielectric layer structure of claim 21, wherein said organic low-k dielectric layer is an organosilicate glass (OSG) layer.

23. The inter-metal dielectric layer structure of claim 22, wherein said organosilicate glass layer is a black diamond layer.

24. The inter-metal dielectric layer structure of claim 21, wherein said organic low-k dielectric layer is an organofluorosilicate glass (OFSG) layer.
